(19) United States
(12) Patent Application Publication
(10) Pub. No.: US 2015/0380221 A1
(43) Pub. Date: Dec. 31, 2015

(54) Hole Pattern For Uniform Illumination Of Workpiece Below A Capacitively Coupled Plasma Source

(71) Applicant: Applied Materials, Inc., Santa Clara, CA (US)

(72) Inventors: Ren Liu, Sunnyvale, CA (US); John C. Forster, Mt. View, CA (US); Joseph Yudovsky, Campbell, CA (US); Somesh Khandelwal, Sunnyvale, CA (US); Kallol Bera, Fremont, CA (US); Li-Qun Xia, Cupertino, CA (US)

(21) Appl. No.: 14/551,537

(22) Filed: Nov. 24, 2014

Related U.S. Application Data
(60) Provisional application No. 62/019,394, filed on Jun. 30, 2014.

(51) Int. Cl. H01J 37/32; C23C 16/56; C23C 16/505; C23C 16/455

(52) U.S. Cl. CPC H01J 37/32807; C23C 16/45536; C23C 16/45551; C23C 16/56; C23C 16/505; H01J 37/32091

(57) ABSTRACT

A plasma source assembly for use with a processing chamber includes a blocker plate with a first set of apertures within an inner electrical center of the blocker plate and smaller apertures around the outer peripheral edge. The apertures can decrease gradually in diameter from the electrical center outward to the peripheral edge or can be in discrete increments with the smallest at the outer peripheral edge.

### CROSS-REFERENCE TO RELATED APPLICATIONS

This application claims priority to U.S. Provisional Application No. 62/019,394, filed Jun. 30, 2014.

### FIELD

Embodiments of the invention generally relate to an apparatus for processing substrates. More particularly, embodiments of the invention relate to modular capacitively coupled plasma sources for use with processing chambers like batch processors.

### BACKGROUND

Semiconductor device formation is commonly conducted in substrate processing platforms containing multiple chambers. In some instances, the purpose of a multi-chamber processing platform or cluster tool is to perform two or more processes on a substrate sequentially in a controlled environment. In other instances, however, a multiple chamber processing platform may only perform a single processing step on substrates; the additional chambers are intended to maximize the rate at which substrates are processed by the platform. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for atomic layer deposition (ALD) processes and some chemical vapor deposition (CVD) processes.

Some ALD systems, especially spatial ALD systems with rotating substrate platens, benefit from a modular plasma source, i.e., a source that can be easily inserted into the system. The plasma source consists of a volume where plasma is generated, and a way to expose a workpiece to a flux of charged particles and active chemical radical species.

Capacitively coupled plasma (CCP) sources are commonly used in these applications as it is easy to generate plasma in a CCP in the pressure range (1-50 Torr) commonly used in ALD applications. An array of holes is often used to expose the wafer to the active species of the plasma. However, it has been found that the relative density of active species is not uniform across the entire array of holes.

Therefore, there is a need in the art for modular capacitively coupled plasma sources which provide increased active species density uniformity.

### SUMMARY

One or more embodiments of the disclosure are directed to plasma source assemblies comprising a housing a blocker plate and an RF hot electrode. The blocker plate is in electrical communication with the housing. The blocker plate has an outer peripheral edge defining a field and a plurality apertures within the field and extending through the blocker plate. The plurality of apertures comprises a first set of apertures having a first diameter and a second set of apertures having a second diameter different from the first diameter. The RF hot electrode is within the housing and has a front face and a back face. The front face of the RF hot electrode is spaced from the blocker plate to define a gap. The first set of apertures are located on an inner portion of the field and the second set of apertures are between the first set of apertures and the outer peripheral edge of the blocker plate.

Additional embodiments of the invention are directed to blocker plates for plasma source assemblies. The blocker plates comprise an outer peripheral edge, an electrical center, at least one first aperture having a first diameter and positioned near the electrical center. A plurality of third apertures are positioned adjacent the outer peripheral edge and defining a field within. The plurality of third apertures have a third diameter different from the first diameter. A plurality of second apertures are within the field between the plurality of third apertures and the at least one first aperture. Each of the plurality of second apertures independently has a second diameter within the range of the third diameter and the first diameter. The second diameter of any second aperture is less than or equal to about a diameter of an aperture adjacent to the second aperture and closer to the at least one first aperture, and greater than or equal to about a diameter of an aperture adjacent to the second aperture and closer to the third apertures.

Further embodiments of the disclosure are directed to methods comprising positioning a substrate in a processing chamber adjacent a blocker plate of a plasma source assembly and generating a plasma within the plasma source assembly so that plasma flows through the blocker plate toward the substrate. The blocker plate has an outer peripheral edge defining a field and a plurality apertures within the field and extending through the blocker plate. The plurality of apertures comprise a first set of apertures having a first diameter and a second set of apertures having a second diameter different from the first diameter. The first set of apertures are located on an inner portion of the field and the second set of apertures are between the first set of apertures and the outer peripheral edge of the blocker plate.

### BRIEF DESCRIPTION OF THE DRAWINGS

So that the manner in which the above recited features of embodiments of the invention can be understood in detail, a more particular description of embodiments of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic plan view of a substrate processing system configured with four gas injector assemblies and four capacitively coupled wedge-shaped plasma sources with a loading station in accordance with one or more embodiments of the invention;

FIG. 2 shows a schematic of a platen rotating a wafer through a pie-shaped plasma region in accordance with one or more embodiment of the invention;

FIG. 3 shows a schematic of a plasma source assembly in accordance with one or more embodiment of the invention;

FIG. 4 shows an expanded view of a portion of the plasma source assembly FIG. 3;

FIG. 5 shows a schematic view of a portion of a plasma source assembly in accordance with one or more embodiment of the invention;

FIG. 6 shows an expanded view of a portion of the plasma source assembly of FIG. 3;

FIG. 7 shows a front view of a blocker plate in accordance with one or more embodiments of the invention;

FIG. 8 shows an expanded view of a portion of the blocker plate of FIG. 7;

FIG. 9 shows a partial view of a wedge-shaped blocker plate in accordance with one or more embodiment of the invention;

FIG. 10 shows an expanded view of a portion of the blocker plate of FIG. 9; and

FIG. 11 shows a plasma source assembly in accordance with one or more embodiment of the invention.

### DETAILED DESCRIPTION

Embodiments of the invention provide a substrate processing system for continuous substrate deposition to maximize throughput and improve processing efficiency. The substrate processing system can also be used for pre-deposition and post-deposition plasma treatments.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

As used in this specification and the appended claims, the terms “reactive gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

As used in this specification and the appended claims, the term “reduced pressure” means a pressure less than about 100 Torr, or less than about 75 Torr, or less than about 50 Torr, or less than about 25 Torr. For example, “medium pressure” defined as in the range of about 1 Torr to about 25 Torr is reduced pressure.

Rotating platen chambers are being considered for many applications. In such a chamber, one or more wafers are placed on a rotating holder (“platen”). As the platen rotates, the wafers move between various processing areas. For example, in ALD, the processing areas would expose the wafer to precursor and reactants. In addition, plasma exposure may be necessary to properly treat the film or the surface for enhanced film growth, or to obtain predetermined film properties. Some embodiments of the invention provide for uniform deposition and post-treatment (e.g., densification) of ALD films when using a rotating platen ALD chamber.

Rotating platen ALD chambers can deposit films by traditional time-domain processes where the entire wafer is exposed to a first gas, purged and then exposed to the second gas, or by spatial ALD where portions of the wafer are exposed to the first gas and portions are exposed to the second gas and the movement of the wafer through these gas streams deposits the layer.

Embodiments of the invention can be used with either a linear processing system or a rotational processing system. In a linear processing system, the width of the area that the plasma exits the housing is substantially the same across the entire length of front face. In a rotational processing system, the housing may be generally “pie-shaped” or “wedge-shaped”. In a wedge-shaped segment, the width of the area that the plasma exits the housing changes to conform to a pie shape. As used in this specification and the appended claims, the terms “pie-shaped” and “wedge-shaped” are used interchangeably to describe a body that is a generally circular sector. For example, a wedge-shaped segment may be a fraction of a circle or disc-shaped structure. The inner edge of the pie-shaped segment can come to a point or can be truncated to a flat edge or rounded. The path of the substrates can be perpendicular to the gas ports. In some embodiments, each of the gas injector assemblies comprise a plurality of elongate gas ports which extend in a direction substantially perpendicular to the path traversed by a substrate. As used in this specification and the appended claims, the term “substantially perpendicular” means that the general direction of movement of the substrates is along a plane approximately perpendicular (e.g., about 45° to 90°) to the axis of the gas ports. For a wedge-shaped gas port, the axis of the gas port can be considered to be a line defined as the mid-point of the width of the port extending along the length of the port.

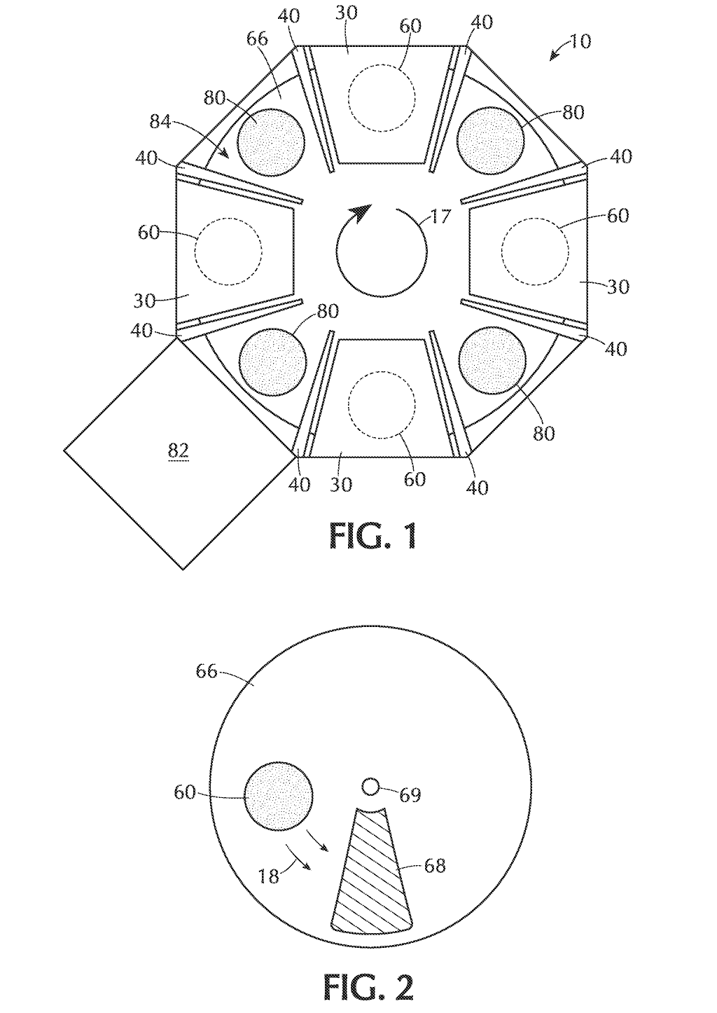

Processing chambers having multiple gas injectors can be used to process multiple wafers simultaneously so that the wafers experience the same process flow. For example, as shown in FIG. 1, the processing chamber 10 has four gas injector assemblies 30 and four wafers 60. At the outset of processing, the wafers 60 can be positioned between the gas injector assemblies 30. Rotating the susceptor 66 of the carousel by 45° will result in each wafer 60 being moved to a gas injector assembly 30 for film deposition. An additional 45° rotation would move the wafers 60 away from the gas injector assemblies 30. This is the position shown in FIG. 1. With spatial ALD injectors, a film is deposited on the wafer during movement of the wafer relative to the injector assembly. In some embodiments, the susceptor 66 is rotated so that the wafers 60 do not stop beneath the gas injector assemblies 30. The number of wafers 60 and gas injector assemblies 30 can be the same or different. In some embodiments, there are the same number of wafers being processed as there are gas injector assemblies. In one or more embodiments, the number of wafers being processed are an integer multiple of the number of gas injector assemblies. For example, if there are four gas injector assemblies, there are 4× wafers being processed, where x is an integer value greater than or equal to one.

The processing chamber 10 shown in FIG. 1 is merely representative of one possible configuration and should not be taken as limiting the scope of the invention. Here, the processing chamber 10 includes a plurality of gas injector assemblies 30. In the embodiment shown, there are four gas injector assemblies 30 evenly spaced about the processing chamber 10. The processing chamber 10 shown is octagonal, however, it will be understood by those skilled in the art that this is one possible shape and should not be taken as limiting the scope of the invention. The gas injector assemblies 30 shown are wedge-shaped, but it will be understood by those skilled in the art that the gas injector assemblies can be rectangular or have other shape. An option for a plasma source is an capacitively coupled plasma. A capacitively coupled plasma is generated via RF potential to an electrode.

The processing chamber 10 includes a substrate support apparatus, shown as a round susceptor 66 or susceptor assembly or platen. The substrate support apparatus, or susceptor 66, is capable of moving a plurality of wafers 60 beneath each of the gas injector assemblies 30. A load lock 82 might be connected to a side of the processing chamber 10 to allow the wafers 60 to be loaded/unloaded from the processing chamber 10.

In some embodiments, the processing chamber 10 comprises a plurality of gas curtains 40 positioned between the gas injector assemblies 30 (also called gas distribution plates or gas distribution assemblies) and the plasma sources 80. Each gas curtain creates a barrier to prevent, or minimize, diffusion of processing gases into other regions of the processing chamber. For example, a gas curtain can prevent or minimize the diffusion of reactive gases from gas injector assemblies 30 from migrating from the gas distribution assembly regions to the plasma source 80 regions and vice versa. The gas curtain can include any suitable combination of gas and/or vacuum streams which can isolate the individual processing sections from the adjacent sections. In some embodiments, the gas curtain 40 is a purge (or inert) gas stream. In one or more embodiments, the gas curtain 40 is a vacuum stream that removes gases from the processing chamber. In some embodiments, the gas curtain 40 is a combination of purge gas and vacuum streams so that there are, in order, a purge gas stream, a vacuum stream and a purge gas stream. In one or more embodiments, the gas curtain is a combination of vacuum streams and purge gas streams so that there are, in order, a vacuum stream, a purge gas stream and a vacuum stream.

Some atomic layer deposition systems benefit from a modular plasma source, i.e. a source that can be easily inserted into the system. Such a source will have all or most of its hardware operating at the same pressure level as the atomic layer deposition process, typically 1-50 Torr. The RF hot electrode creates the plasma in a 8.5 mm gap (the gap can range from 3 mm to 25 mm) between the hot electrode and a grounded electrode.

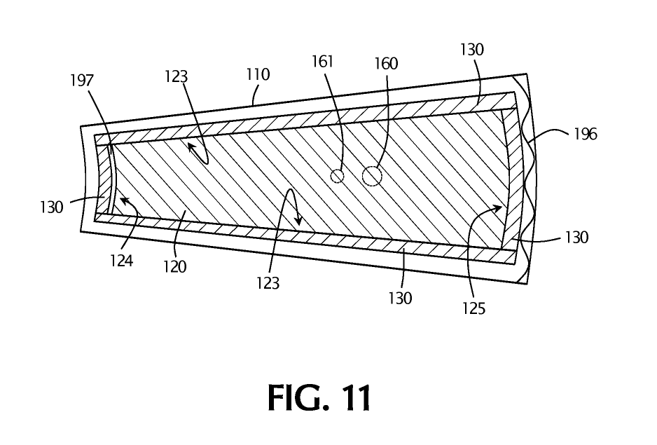

The upper portion of the electrode may be covered by a thick dielectric (e.g., ceramic), which in turn may be covered by a grounded surface. The RF hot electrode and grounded structure are made of a good conductor, such as aluminum. To accommodate thermal expansion, two pieces of dielectric (e.g. ceramic) are placed at the long ends of the RF hot electrode. For example, grounded Al pieces are placed adjacent to the dielectric, without a gap between. The grounded pieces can slide inside the structure, and may be held against the ceramic with springs. The springs compress the entire “sandwich” of grounded Al/dielectric against the RF hot electrode without any gaps, eliminating or minimizing chance of spurious plasma. This holds the parts together, eliminating gaps, yet still allows some sliding due to thermal expansion. In some embodiments, as shown in FIG. 11, there is one spring on the outer end of the assembly and a gap adjacent the inner end. In the wedge-shaped embodiment shown, the gap allows for the expansion of the hot electrode without being damaged and/or without damaging the end dielectric 130.

Exposure of the wafer to the active species generated of the plasma is commonly accomplished by allowing the plasma to flow through an array of holes. The dimensions of the holes determine the relative abundances of active species arriving at the wafer surface. Holes that “run hot”, e.g. holes that provide charged particle flux in excess of neighboring holes can lead to non-uniformity in processing, and can lead to process induced damage to the wafer. Some embodiments of the invention increase the uniformity of plasma flux out of all holes in the array. The wafer surface can be any suitable distance from the front face of the blocker plate 112. In some embodiments, the distance between the front face of the blocker plate 112 and the wafer surface is in the range of about 8 mm to about 16 mm, or in the range of about 9 mm to about 15 mm, or in the range of about 10 mm to about 14 mm, or in the range of about 11 mm to about 13 mm or about 12 mm.

The inventors have found that, in an array of holes having a diameter of 4 mm and a depth of 3 mm, plasma is generated inside the holes. The inventors have also surprisingly been found that holes closer to the edge have a higher plasma density compared to the inner holes. The inventors have also found that the proximity of adjacent holes, determines whether holes are “hot” (higher plasma density) or holes have “normal” plasma density.

Embodiments of the disclosure provide a plasma source assembly with increased plasma density uniformity across all holes. In some embodiments, the diameter of the holes decreases in increments. In some embodiments, the gradual reduction of hole diameter towards the edge of the array provides increased uniformity. It has been surprisingly found that the edge holes have higher plasma density compared to interior holes. If the edge holes are made smaller, the plasma density in these holes is lower. By making edge holes smaller than interior holes, the charged species flux can be made more uniform for all holes. The spacing between the large diameter and smaller diameter holes has also been found to affect the plasma density uniformity.

The geometry of the holes, such as aspect ratio, can be selected to provide an appropriate ion to neutral radical flux ratio. In addition, the inventors have found that the aspect ratio is a parameter that can affect the plasma density in the holes.

In some embodiments, the hole diameter is gradually reduced from a maximum at, or near, the electrical center of a front face of a plasma source to a minimum around the edges of the front face. For a circular front face, the gradual reduction may be approximately the same extending from the center of the face toward the edge along any radial direction. In a non-circular face, the rate of reduction in hole diameters may be varied depending on the distance between the electrical center and the edge of the front face.

In one or more embodiments, a field of 4 mm diameter holes is surrounded by 2 mm diameter holes, which are surrounded by 1.3 mm diameter holes. Using the three different hole diameters may provide an acceptable tradeoff between complexity and gradual reduction in hole diameter.

Without being bound by any particular theory of operation, it is believed that the path of the plasma return current is responsible for the increased propensity of isolated/outer holes to run “hot”. If the plasma density in the source peaks toward the edge holes, the diameter of the edge holes can be reduced further to increase plasma density uniformity.

The coaxial RF feed may be constructed so that the outer conductor terminates on the grounded plate. The inner conductor can terminate on the RF hot electrode. If the feed is at atmospheric pressure, O-rings may be positioned at the bottom of the feed structure to enable medium pressure inside the source. In some embodiments, the gas is fed to the source around the outside periphery of the coaxial feed. In one or more embodiments, the gas is fed through another port 161 near the RF feed. For example, the embodiment shown in FIG. 11 includes a separate RF fee line 160 and gas port 161.

In order for gas to reach the plasma volume, the ground plate, thick ceramic, and RF hot electrode might be perforated with through holes. The size of the holes may be small enough to prevent ignition inside the holes. For the ground plate and RF hot electrode, the hole diameter of some embodiments is <1 mm, for example about 0.5 mm. The high electric fields inside the dielectric may help eliminate or minimize the chances of stray plasma in the holes.

The RF feed may be in the form of a coaxial transmission line. The outer conductor is connected/terminated in the grounded plate, and the inner conductor is connected to the RF hot electrode. The grounded plate can be connected to the metal enclosure or housing by any suitable method including, but not limited to, a metal gasket. This helps to ensure a symmetric geometry of the return currents. All return currents flow up the outer conductor of the feed, minimizing RF noise.

The plasma source of one or more embodiments can be rectangular in shape or can be configured to other shapes. For a spatial ALD application utilizing a rotating wafer platen, the shape may be a truncated wedge, as shown in FIG. 2. The design retains the atmospheric coaxial RF feed and the dielectric layers with offset gas feed holes. The plasma uniformity can be tuned by adjusting the spacing between the RF hot electrode and the grounded exit plate, and by adjusting the location of the RF feedpoint.

In some embodiments, the source is operated at medium pressure (1-50 Torr), yet the coaxial feed is kept at atmospheric pressure.

In some embodiments, the gas feed is through perforations or holes in the ground plate, RF hot electrode and dielectric isolator. The dielectric isolator of some embodiments is split into three layers. The holes in the dielectric layers may be offset from each other, and there may be thin setbacks between layers to allow gas to flow between the offset holes. The offset holes in the dielectric layers minimize the chance of ignition. The gas feed to the source assembly occurs around the outside periphery of the outer conductor of the coaxial RF feed.

In some embodiments, the RF feed is designed to provide symmetric RF feed current to the hot plate, and symmetric return currents. All return currents flow up the outer conductor, minimizing RF noise, and minimizing impact of source installation on operation.

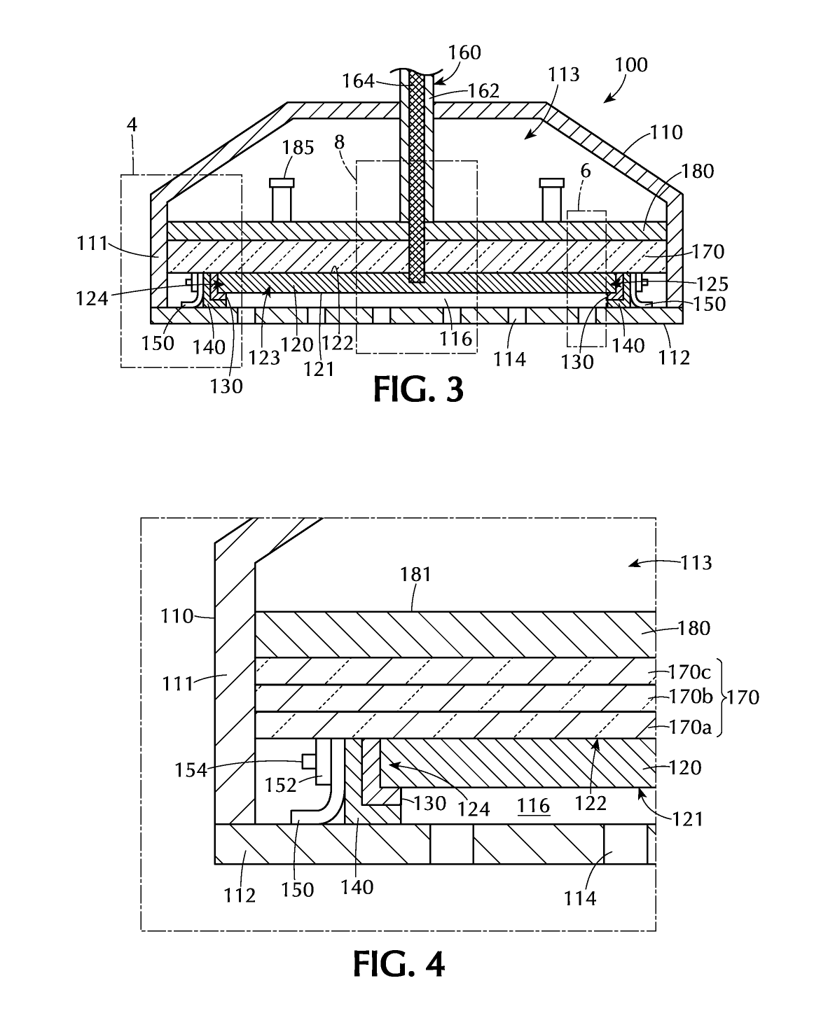

Referring to FIGS. 3 through 8, one or more embodiments of the invention are directed to modular capacitively coupled plasma sources 100. As used in this specification and the appended claims, the term “modular” means that plasma source 100 can be attached to or removed from a processing chamber. A modular source can generally be moved, removed or attached by a single person.

The plasma source 100 includes a housing 110 with a blocker plate 112 and a gas volume 113. The blocker plate 112 is electrically grounded and, in conjunction with the hot electrode 120 forms a plasma in gap 116. The blocker plate 112 has a thickness with a plurality of apertures 114 extending therethrough to allow plasma ignited in the gap 116 to pass through the apertures 114 into a processing region on an opposite side of the blocker plate 112 from the gap 116.

The housing 110 can be round, square or elongate, which means that, when looking at the face of the blocker plate 112, there is a long axis and a short axis. For example, a rectangle having two long sides and two short sides would create an elongate shape with an elongate axis extending between the two long sides. In some embodiments, the housing 110 is wedge shaped having two long sides a short end and a long end. The short end can actually come to a point. Either or both of the short end and long end can be straight or curved.

The plasma source 100 includes an RF hot electrode 120. This electrode 120 is also referred to as the “hot electrode”, “RF hot”, and the like. The elongate RF hot electrode 120 has a front face 121, a back face 122 and elongate sides 123. The hot electrode 120 also includes a first end 124 and second end 125 which define the elongate axis. The elongate RF hot electrode 120 is spaced from the blocker plate 112 of the housing so that a gap 116 is formed between the front face 121 of the hot electrode 120 and the blocker plate 112 of the housing 110. The elongate RF hot electrode 120 can be made of any suitable conductive material including, but not limited to, aluminum.

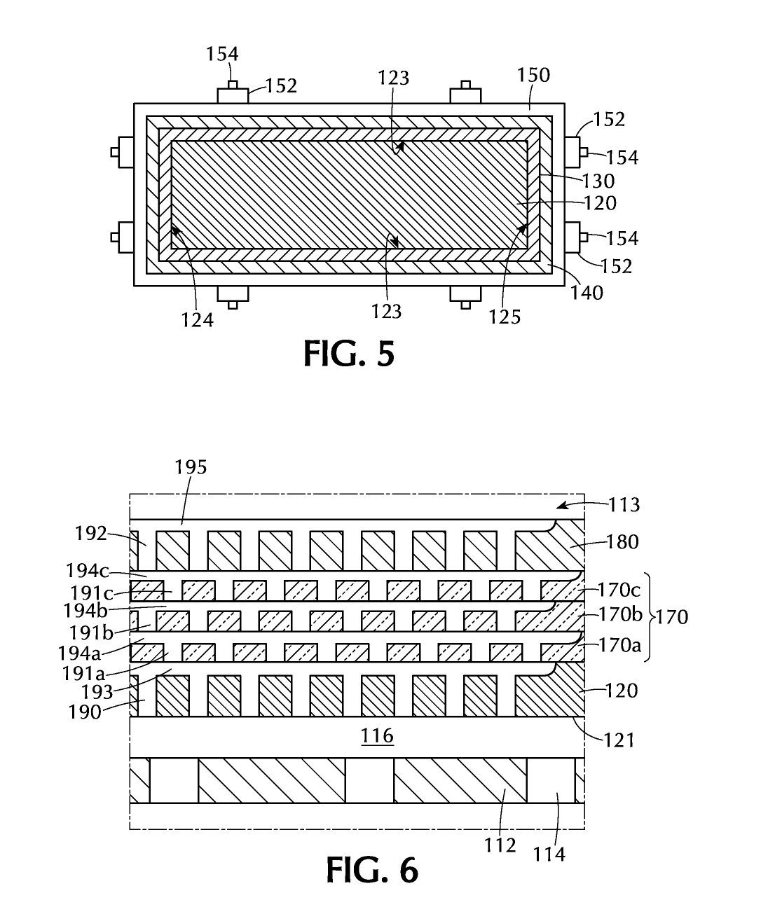

As shown in the expanded view of FIG. 5, some embodiments include an end dielectric 130 in contact with one or more of the first end 124 and the second end 125 of the RF hot electrode 120. The end dielectric 130 is positioned between the RF hot electrode 120 and the side wall 111 of the plasma source 100 to electrically isolate the hot electrode from electrical ground. In one or more embodiments, the end dielectric 130 is in contact with both the first end 124 and the second end 125 of the hot electrode 120. The end dielectric 130 can be made out of any suitable dielectric material including, but not limited to ceramic. The end dielectric 130 shown in the Figures is L-shaped, but any suitable shape can be used.

A sliding ground connection 140 may be positioned at one or more of the first end 124 and the second end 125 of the RF hot electrode 120 or the sides. The sliding ground connection 140 is positioned on an opposite side of the end dielectric 130 from the hot electrode 120. The sliding ground connection 140 is isolated from direct contact with the RF hot electrode 120 by the end dielectric 130. The sliding ground connection 140 and the end dielectric 130 cooperate to maintain a gas tight seal and allow the hot electrode 120 to expand without allowing leakage of gases around the side of the electrode. The sliding ground connection 140 is a conductive material and can be made of any suitable material including, but not limited to, aluminum. The sliding ground connection 140 provides a grounded termination to the side of the end dielectric 130 to ensure that there is no electric field, thereby minimizing the chance of stray plasma to the side of the end dielectric 130.

A seal foil 150 may be positioned at the sliding ground connection 140 on an opposite side from the end dielectric 130. The seal foil 150 forms an electrical connection between the blocker plate 112 of the housing 110 and the sliding ground connection 140 as the sliding ground connection 140 slides on the blocker plate 112. The seal foil 150 can be made from any suitable conductive material including, but not limited to, aluminum. The seal foil 150 can be a thin flexible material that can move with the expansion and contraction of the hot electrode 120 so long as the electrical connection between the front face and the sliding ground connection is maintained.

Referring to FIG. 5, which shows one end of the plasma source 100, a clamp face 152 and nut 154 are positioned at the end of the hot electrode 120, end dielectric 130, sliding ground connection 140 and seal foil 150 combination. Other clamp faces 152 and nuts 154 can be found at any side of the combination and multiple can be found along each side of the combination, depending on the size and shape of the plasma source. The clamp face 152 and nut 154 provide inwardly directed pressure to the combination of components to form a tight seal and prevent separation between the end dielectric 130 and the sliding ground connection 140 which might allow plasma gases to get behind the hot electrode 120. The clamp face 152 and nut 154 can be made from any suitable material including, but not limited to, aluminum and stainless steel.

In some embodiments, a dielectric spacer 170 is positioned adjacent the back face 122 of the elongate RF hot electrode 120. The dielectric spacer 170 can be made of any suitable dielectric material including, but not limited to, ceramic materials. The dielectric spacer 170 provides a non-conductive separator between the RF hot electrode 120 and the top portion of the housing 110. Without this non-conductive separator, there is a chance that a plasma could be formed in the gas volume 113 due to capacitive coupling between the RF hot electrode 120 and the housing 110.

The dielectric spacer 170 can be any suitable thickness and made up of any number of individual layers. In the embodiment shown in FIG. 4, the dielectric spacer 170 is made up of one layer. In an alternate embodiment shown in FIG. 6, the dielectric spacer 170 comprises three individual dielectric spacer sub-layers 170a, 170b, 170c. The combination of these sub-layers makes up the total thickness of the dielectric spacer 170. Each of the individual sub-layers can be the same thickness or each can have an independently determined thickness.

Above the dielectric spacer 170, in some embodiments, is a grounded plate 180 positioned within the housing 110 and on an opposite side of the dielectric spacer 170 from the RF hot electrode 120. The grounded plate 180 is made of any suitable electrically conductive material including, but not limited to, aluminum, which can be connected to electrical ground. This grounded plate 180 further isolates the RF hot electrode 120 from the gas volume 113 to prevent plasma formation in the gas volume 113 or in a region other than the gap 116 where the plasma is intended to be formed.

Although the Figures show the grounded plate 180 to be about the same thickness as the dielectric spacer 170, or the sum of the individual dielectric spacer layers, this is merely one possible embodiment. The thickness of the grounded plate 180 can be any suitable thickness depending on the specific configuration of the plasma source. The thickness of the grounded plate in some embodiments is chosen based on, for example, thin enough to make drilling of gas holes easier, but thick enough to withstand the forces of the various springs mentioned. Additionally, the thickness of the grounded pate 180 may be tuned to ensure that the coaxial feed, which is typically a welded connection, can be adequately attached.

Some embodiments of the invention include a plurality of compression elements 185. The compression elements 185 direct force against a back surface 181 of the grounded plate 180 in the direction of the RF hot electrode 120. The compressive force causes the grounded plate 180, dielectric spacer 170 and RF hot electrode 120 to be pressed together to minimize or eliminate any spacing between each adjacent component. The compressive force helps prevent gases from flowing into the space being the RF hot electrode where they may become stray plasma. Suitable compression elements 185 are those which can be adjusted or tuned to provide a specific force to the back surface 181 of the grounded plate 180 and include, but are not limited to, springs and screws.

With reference to FIG. 6, some embodiments of the invention include a plurality of holes 190, 191a, 191b, 191c, 192 extending through one or more of the grounded plate 180, dielectric spacer 170 and RF hot electrode 120. While the embodiment of FIG. 6 shows a dielectric spacer 170 having three layers 170a, 170b, 170c, it will be understood that there can be any number of dielectric spacer 170 layers, and that this is merely one possible configuration. The holes allow a gas to move from the gas volume 113 to the gap 116 adjacent the front face 121 of the RF hot electrode 120.

In the embodiment shown in FIG. 6, the plurality of holes 190 in the RF hot electrode 120 are offset from the plurality of holes 191a in the first layer of the dielectric spacer 170a which are offset from the plurality of holes 191b in the second layer of the dielectric spacer 170b which are offset from the plurality of holes 191c in the third layer of the dielectric spacer 170c which are offset from the plurality of holes 192 in the grounded plate 180. This offset pattern helps prevent or minimize the possibility of stray plasma forming outside of the gap 116 because there is no direct line between the RF hot electrode 120 and the grounded plate 180 or the gas volume 113. Without being bound by any particular theory of operation, it is believed that the sub-layers minimize the chance of ignition of a plasma in the gas feed holes.

A channel 193, 194a, 194b, 194c, 195 can be formed in each of the back face 122 of the RF hot electrode 120 and the back face of each layer of the dielectric spacer 170. This allows the gas flowing from the adjacent plurality of holes to be in fluid communication with the plurality of holes in the adjacent component. A channel 195 is shown in the back surface 181 of the grounded plate 180, but it will be understood that this channel 195 is not necessary to provide fluid communication between the gas volume 113 and the gap 116.

The size of the plurality of holes 190, 191a, 191b, 191c, 192 can vary and has an impact of the flow rate of gas from the gas volume 113 to the gap 116. Larger diameter holes will allow more gas to flow through than smaller diameter holes. However, larger diameter holes may also make ignition of stray plasma within the holes easier. In some embodiments, each of the plurality of holes 190, 191a, 191b, 191c, 192 independently has a diameter less than about 1.5 mm, or less than about 1.4 mm, or less than about 1.3 mm, or less than about 1.2 mm, or less than about 1.1 mm or less than about 1 mm.

Similarly, the depth of the channel 193, 194, 195 can also impact the flow rate of gas and likelihood of stray plasma formation. In some embodiments, each of the channels 193, 194, 195 independently has a depth of less than about 1 mm, or less than about 0.9 mm, or less than about 0.8 mm, or less than about 0.7 mm or less than about 0.6 mm, or less than about 0.5 mm, or about 0.5 mm. The depth of each individual channel is measured from the back surface of the respective component. For example, the depth of the channel 195 in the grounded plate 180 is measured from the back surface 181 of the grounded plate 180. In some embodiments, the plurality of holes 190, 191a, 191b, 191c passing through each of the dielectric spacer layers 170a, 170b, 170c and the RF hot electrode 120 have diameters greater than the depth of the channel 193, 194a, 194b, 194c in the respective component.

Referring to FIG. 3, a coaxial RF feed line 160 passes through the elongate housing 110 and provides power for the RF hot electrode 120 to generate the plasma in the gap 116. The coaxial RF feed line 160 includes an outer conductor 162 and an inner conductor 164 separated by an insulator 166 [added clarification to the figure]. The outer conductor 162 is in electrical communication with electrical ground and the inner conductor 164 is in electrical communication with the elongate RF hot electrode 120. As used in this specification and the appended claims, the term “electrical communication” means that the components are connected either directly or through an intermediate component so that there is little electrical resistance.

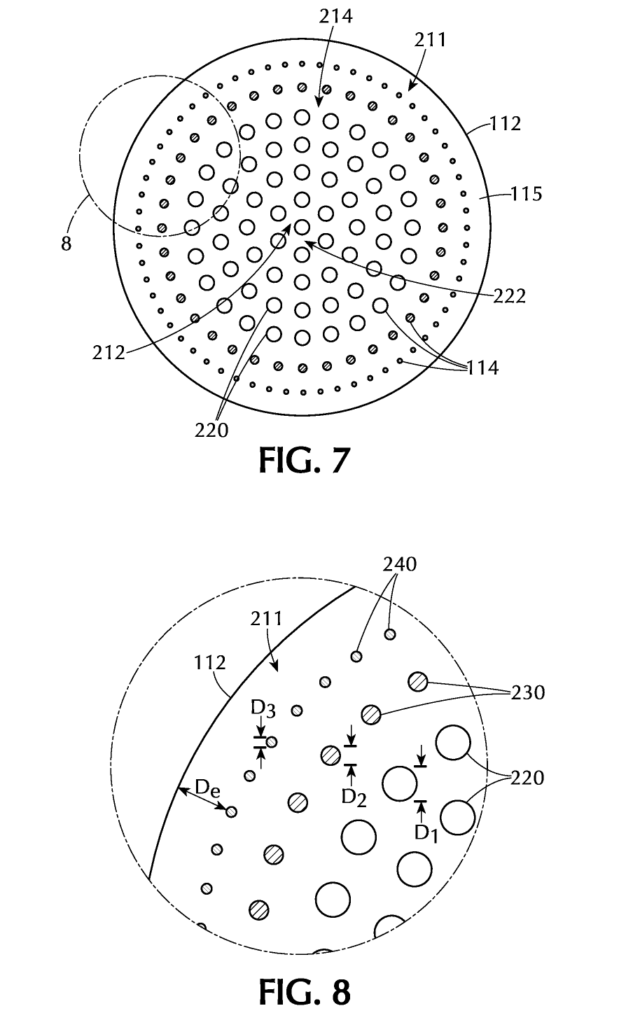

FIGS. 7 through 9 show blocker plates 112 in accordance with embodiments of the invention. FIG. 7 shows a round blocker plate 112 which can be used with a round plasma source assembly (not shown). The view shown in the Figures is of the front face 115 of the blocker plate 112. This is the face that would be “seen” by a substrate being processed.

The blocker plate 112 includes an outer peripheral edge 211 and an electrical center 212. The electrical center 212 of the embodiment shown in FIG. 7 is located at about the center of the blocker plate 112. The outer peripheral edge 211 defines a field 214. A plurality of apertures 114 are positioned within the field 214 and extending through the blocker plate 112.

The plurality of apertures 114 comprises a first set of apertures 220 and a second set of apertures 230. The first set of apertures 220 has a first diameter D1 and the second set of apertures has a second diameter D2 which is different from the first diameter D1. The first set of apertures 220 are located on an inner portion 222 of the field 214 and the second set of apertures 230 are between the first set of apertures 220 and the outer peripheral edge 211 of the blocker plate 112.

In some embodiments, as shown in FIGS. 7 and 8, a third set of apertures 240 are positioned between the second set of apertures 230 and the outer peripheral edge 211 of the blocker plate 112. The third set of apertures 240 has a third diameter D3 different from the first diameter D1 and the second diameter D2.

The diameter of the first set of apertures 220, the second set of apertures 230 and the third set of apertures 240 can be varied based on a number of factors including, but not limited to, the size of the blocker plate, the shape of the blocker plate, the intended plasma power and frequency. In some embodiments, the first diameter D1 is in less than about 10 mm, or less than about 9 mm, or less than about 8 mm, or less than about 7 mm, or less than about 6 mm, or less than about 5 mm, or less than about 4 mm or less than about 3 mm. In some embodiments, the first diameter D1 is in the range of about 2 mm to about 10 mm, or in the range of about 1 mm to about 8 mm, or in the range of about 1.5 mm to about 8 mm, or in the range of about 2 mm to about 6 mm, or in the range of about 3 mm to about 5 mm. In one or more embodiments, the first diameter is about 4 mm.

The second diameter D2 of the second set of apertures 230 can vary depending on, for example, the first diameter D1. The second diameter D2 is generally smaller than the first diameter D1, although not necessary to be smaller. The second diameter D2 of some embodiments is less than about 8 mm, or less than about 7 mm, or less than about 6 mm, or less than about 5 mm, or less than about 4 mm, or less than about 3 mm, or less than about 2 mm or less than about 1 mm. In some embodiments, the second diameter D2 is in the range of about 0.5 mm to about 6 mm, or in the range of about 0.75 mm to about 5 mm, or in the range of about 1 mm to about 4 mm, or in the range of about 2 mm to about 3 mm. In one or more embodiments, the second diameter D2 is about 2 mm.

In some embodiments, the second diameter D2 can be in any of the ranges or maximum values previously states as long as the second diameter D2 is less than the first diameter D1. For example, the first diameter D1 can be in the range of about 2 mm to about 6 mm and the second diameter D2 can be in the range of about 1 mm to about 3 mm. In this arrangement, with the second diameter D2 smaller than the first diameter D1, if the first diameter D1 is 2 mm than the second diameter D2 is in the range of about 1 mm to less than 2 mm.

The ratio of the second diameter D2 to the first diameter D1 can be any suitable ratio. For example, the D2:D1 ratio can be in the range of about 1:10 to less than about 2:1, or in the range of about 1:8 to about 1:1, or in the range of about 1:5 to less than about 1:1, or in the range of about 1:3 to less than about 1:1, or in the range of about 1:2 to less than about 1:1. In some embodiments, the second diameter D2 is about the square root of the first diameter D1. In one or more embodiments, the first diameter D1 is about 4 mm and the second diameter D2 is about 2 mm.

In embodiments having a third set of apertures, the third diameter D3 of the third set of apertures 240 can vary depending on, for example, the first diameter D1 and the second diameter D2. The third diameter D3 is generally smaller than the second diameter D2, although not necessary to be smaller. The third diameter D3 of some embodiments is less than about 6 mm, or less than about 5 mm, or less than about 4 mm, or less than about 3 mm, or less than about 2 mm, or less than about 1 mm, or less than about 0.75 mm or less than about 0.5 mm. In some embodiments, the third diameter D3 is in the range of about 0.25 mm to about 4 mm, or in the range of about 0.5 mm to about 3 mm, or in the range of about 0.75 mm to about 2 mm, or in the range of about 1 mm to about 1.5 mm. In one or more embodiments, the third diameter D3 is about 1.3 mm.

In some embodiments, the third diameter D3 can be in any of the ranges or maximum values previously states as long as the third diameter D3 is less than the second diameter D2 and the first diameter D1. For example, the first diameter D1 can be in the range of about 2 mm to about 6 mm and the second diameter D2 can be in the range of about 1 mm to about 3 mm and the third diameter D3 can be in the range of about 0.5 mm to about 2 mm. In this arrangement, with the third diameter D3 smaller than the second diameter D2 and the first diameter D1, if the first diameter D1 is 2 mm than the second diameter is in the range of about 1 mm to less than 2 mm, and the third diameter D3 is in the range of about 0.5 mm to about the second diameter D2.

The ratio of the third diameter D3 to the second diameter D2 can be any suitable ratio. For example, the D3:D2 ratio can be in the range of about 1:10 to less than about 2:1, or in the range of about 1:8 to about 1:1, or in the range of about 1:5 to less than about 1:1, or in the range of about 1:3 to less than about 1:1, or in the range of about 1:2 to less than about 1:1. In some embodiments, the third diameter D3 is about the square root of the second diameter D2. In one or more embodiments, the first diameter D1 is about 4 mm and the second diameter D2 is about 2 mm and the third diameter D3 is about 1.3 mm.

In some embodiments, the smallest set of apertures, for example the third set of apertures, are spaced from the outer peripheral edge 211 of the blocker plate 112 an edge distance De. The edge distance De can be in the range of about 1 mm to about 15 mm, or in the range of about 2 mm to about 10 mm, or in the range of about 3 mm to about 8 mm. In some embodiments the edge distance is less than about 15 mm, or less than about 12 mm, or less than about 10 mm, or less than about 8 mm, or less than about 6 mm, or less than about 5 mm, or less than about 3 mm or less than about 2 mm. Referring to FIG. 8, the edge distance De is shown as the distance from the outer peripheral edge of the blocker plate to the closest portion of each of the third set of apertures.

Referring again to FIG. 8, in some embodiments, the spacing between each of the first set of apertures 220 is substantially the same. In some embodiments, the spacing between each of the second set of apertures 230 are substantially the same. In some embodiments, the spacing between each of the third set of apertures 240 are substantially the same. As used in this specification and the appended claims, the term “substantially the same” used in this respect means that the distance between adjacent apertures of the same size does not vary by more than 10% relative to the average distance between apertures.

FIGS. 7 and 8 show an embodiment of the invention in which there are substantially three sets of apertures. As used in this specification and the appended claims, the term “substantially [x] sets of apertures” means that the diameter of the individual holes can vary so that there are, from a global perspective, x number of different sizes of holes. Small fluctuations in hole diameter, therefore, do not create a new set of apertures. The first set of apertures 220 are positioned within a region around the electrical center 212. The second set of apertures 230 are positioned around the first set of apertures 220. The third set of apertures 240 are positioned around the second set of apertures 230 and adjacent the outer peripheral edge 211 of the blocker plate 112.

Again, as shown in FIG. 8, there can be any number of rows of apertures in each set of apertures. Here, two rows of first sets of apertures 220 can be seen although it will be understood from comparison with FIG. 7 that there may be many more rows of first sets of apertures 220. There is a single row of second set of apertures 230 and a single row of third set of apertures 240. While only a single row of each of the second set of apertures 230 and the third set of apertures 240 are shown, it will be understood that there can be any number of rows. For example, there can in the range of about 1 to about 10 rows of the smallest set of apertures, or the second smallest set of apertures. In one or more embodiments, there is one row of second set of apertures and one row of third set of apertures.

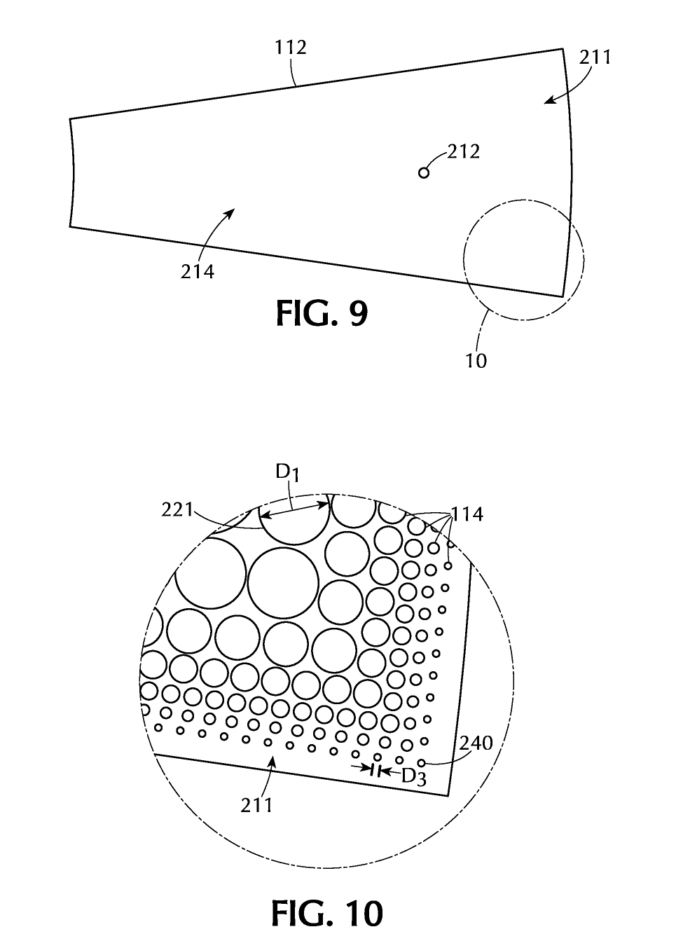

Turning to FIGS. 9 and 10, a blocker plate 112 with a wedge shape can be seen. FIG. 9 shows the wedge shape without the individual apertures drawn for clarity purposes only. The individual apertures can be seen in FIG. 10, which shows the bottom right corner of the wedge shape. In some embodiments, the field 214 includes apertures 114 with different diameters positioned therein. The diameters of the apertures within the field 214 gradually decrease from the first diameter D1 in an inner portion of the field 214 to the outermost and smallest aperture, marked as D3. In this embodiment, there are apertures ranging in diameter from the first diameter D1 to the second diameter D3 with a gradient of diameters in between.

Some embodiments of the invention are directed to blocker plates 112 for use with a plasma source assembly. Referring again to FIGS. 9 and 10, the blocker plate includes an outer peripheral edge 211 with an electrical center 212. The electrical center 212 is based on, for example, the shape of the blocker plate. The electrical center 212 will vary depending on the particular shape of the blocker plate and the intended position that the coaxial RF feed line will connect with the RF hot electrode.

The blocker plate 112 includes at least one first aperture having a first diameter and positioned near the electrical center. For example, a single aperture can be positioned directly at the electrical center 212 or there can be several apertures positioned around the electrical center 212. There can be a single aperture with the largest diameter or a plurality of apertures with the largest diameter. For example, a large portion of the field may be occupied by the largest diameter apertures, with a gradient of diameters beginning several rows from the edge. Referring to FIG. 10, a single large diameter aperture 221 is shown with six rows of decreasing diameter apertures. The main field 214 of the blocker plate 112 includes apertures with the same diameter and the largest diameter aperture 221 shown and six rows of smaller diameter apertures surrounding the field 214.

In the embodiment shown, a plurality of third apertures 240 are positioned adjacent to the outer peripheral edge 211 of the blocker plate 112. The plurality of third apertures 240 defines the boundary of the field 214. A plurality of second apertures 230 are positioned between the largest diameter aperture 221 and the plurality of third apertures 240.

While three sets of apertures have been shown in the drawings, it will be understood that this is merely representative and should not be taken as limiting the scope of the disclosure. In some embodiments, there are two sets of apertures, a plurality of first apertures with a first diameter and a plurality of second apertures with a second diameter smaller than the first diameter. In some embodiments, there are three sets of apertures, with the plurality of third apertures having a different diameter than the first diameter and the second diameter. In one or more embodiments, there are four sets of apertures; a plurality of first apertures with a first diameter, a plurality of second apertures with a second diameter, a plurality of third apertures with a third diameter and a plurality of fourth apertures with a fourth diameter. Each of the first diameter, second diameter, third diameter and fourth diameter being different. In some embodiments, there are five, six, seven, eight, nine or more sets of apertures with each set of apertures comprising at least one aperture and each set having a different diameter than apertures positioned adjacent.

Additional embodiments of the invention are directed to methods comprising positioning a substrate in a processing chamber adjacent a blocker plate of a plasma source assembly. The blocker plate being any of the various embodiments described herein. A plasma is then generated in the plasma source and allowed to flow through the apertures in the blocker plate toward the substrate.

It may be useful for a plasma treatment to occur uniformly across the wafer as the wafer moves through the plasma region. In the carousel-type embodiment shown in FIG. 1, the wafer is rotating through a plasma region, making exposure to the plasma across the wafer surface more variable than for a linearly moving wafer. One method to ensure uniformity of the plasma process is to have a “wedge-shaped” or “pie-shaped” (circular sector) plasma region of uniform plasma density, as shown in FIG. 2. The embodiment of FIG. 2 shows a simple platen structure, also referred to as a susceptor or susceptor assembly, with a single wafer 60. As the susceptor 66 rotates the wafer 60 along an arcuate path 18, the wafer 60 passes through a plasma region 68 which has a wedge-shape. Because the susceptor is rotating about the axis 69, different portions of the wafer 60 will have different annular velocities, with the outer peripheral edge of the wafer moving faster than the inner peripheral edge. Therefore, to ensure that all portions of the wafer have about the same residence time in the plasma region, the plasma region is wider at the outer peripheral edge than at the inner peripheral edge.

FIG. 11 shows an embodiment of a wedge-shaped plasma source assembly in accordance with one or more embodiment of the invention. The housing 110 is shown with the hot electrode 120 and end dielectric 130 but it will be understood that other components, as shown in the Figures and described herein, can be included. The end dielectric 130 is shown as multiple pieces with straight components along the elongate sides 123 and curved components adjacent the first end 124 (also referred to as the inner end or inner peripheral end) and the second end 125 (also referred to as the outer end or outer peripheral end). A spring 196 is positioned adjacent the second end 125 to push the end dielectric 130 against the hot electrode 120 at the second end 125. A gap 197 is between the hot electrode 120 and the end dielectric 130 adjacent the first end 124. The gap 197 shown may allow the hot electrode 120 to expand toward the first end 124 without being damaged or causing damage to the end dielectric 130. In some embodiments, there is a second spring (not shown) positioned to apply pressure to the end dielectric 130 adjacent the first end 124 toward the hot electrode 120. The gap 196 can be any suitable size depending on, for example, the size or width of the hot electrode 120. In some embodiments, the gap is less than about 1.0 mm, or 0.9 mm, or 0.8 mm, or 0.7 mm, or 0.6 mm, or 0.5 mm, or 0.4 mm. In one or more embodiments, the gap 197 is in the range of about 0.3 mm to about 0.7 mm when the plasma source assembly is at room temperature. In some embodiments the gap is about 0.5 mm.

Some embodiments of the invention are directed to processing chambers comprising at least one capacitively coupled wedge-shaped plasma source 100 positioned along an arcuate path in a processing chamber. As used in this specification and the appended claims, the term “arcuate path” means any path which travels at least a portion of a circular-shaped or an oval-shaped path. The arcuate path can include the movement of the substrate along a portion of the path of at least about 5°, 10°, 15°, 20°,

Additional embodiments of the invention are directed to methods of processing a plurality of substrates. The plurality of substrates is loaded onto substrate support in a processing chamber. The substrate support is rotated to pass each of the plurality of substrates across a gas distribution assembly to deposit a film on the substrate. The substrate support is rotated to move the substrates to a plasma region adjacent a capacitively coupled pie-shaped plasma source generating substantially uniform plasma in the plasma region. This is repeated until a film of predetermined thickness is formed.

Rotation of the carousel can be continuous or discontinuous. In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where the carousel can pause again. Pausing between the injectors may provide time for additional processing between each layer deposition (e.g., exposure to plasma).

The frequency of the plasma may be tuned depending on the specific reactive species being used. Suitable frequencies include, but are not limited to, 400 kHz, 2 MHz, 13.56 MHz, 27 MHz, 40 MHz, 60 MHz and 100 MHz.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or the substrate can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus are disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

During processing, the substrate can be heated or cooled. Such heating or cooling can be accomplished by any suitable means including, but not limited to, changing the temperature of the substrate support (e.g., susceptor) and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

While the foregoing is directed to embodiments of the present invention, other and further embodiments of the invention may be devised without departing from the basic scope thereof, and the scope thereof is determined by the claims that follow.

What is claimed is:

1. A plasma source assembly comprising:
a housing;
a blocker plate in electrical communication with the housing, the blocker plate having an outer peripheral edge defining a field and a plurality of apertures within the field and extending through the blocker plate, the plurality of apertures comprising a first set of apertures having a first diameter and a second set of apertures having a second diameter different from the first diameter; and
an RF hot electrode within the housing, the RF hot electrode having a front face and a back face, the front face of the RF hot electrode spaced from the blocker plate to define a gap,
wherein the first set of apertures are located on an inner portion of the field and the second set of apertures are between the first set of apertures and the outer peripheral edge of the blocker plate.

2. The plasma source assembly of claim 1, wherein the first diameter is in the range of about 2 mm to about 10 mm.

3. The plasma source assembly of claim 2, wherein the second diameter is in the range of about 1 mm to about 4 mm.

4. The plasma source assembly of claim 1, further comprising a third set of apertures between the second set of apertures and the outer peripheral edge of the blocker plate, the third set of apertures having a third diameter different from the first diameter and the second diameter.

5. The plasma source assembly of claim 4, wherein the first diameter is about 4 mm and the second diameter is about 2 mm and the third diameter is about 1.3 mm.

6. The plasma source assembly of claim 4, wherein the third diameter is smaller than the second diameter and the second diameter is smaller than the first diameter.

7. The plasma source assembly of claim 4, wherein the third set of apertures is spaced from the outer peripheral edge by a distance less than about 15 mm.

8. The plasma source assembly of claim 4, wherein the third diameter is in the range of about 0.5 mm to about 3 mm.

9. The plasma source assembly of claim 4, wherein the first diameter is in the range of about 2 mm to about 10 mm and the second diameter is in the range of about 1 mm to about 6 mm and the third diameter is in the range of about 0.5 mm to about 3 mm and the first diameter is greater than the second diameter and the second diameter is greater than the third diameter.

10. The plasma source assembly of claim 4, wherein each of the third set of apertures are substantially evenly spaced from adjacent apertures having the third diameter.

11. The plasma source assembly of claim 1, further comprising apertures with different diameters positioned within the field so that the diameters increase gradually from the first diameter in the inner portion of the field to the second diameter at an outer portion of the field.

12. The plasma source assembly of claim 1, wherein the RF hot electrode is elongate with sides, a first end and a second end defining an elongate axis.

13. The plasma source assembly of claim 12, further comprising:
an end dielectric in contact with each of the first end and the second end of the RF hot electrode and between the RF hot electrode and side wall;
a sliding ground connection positioned at one or more of the first end and the second end of the RF hot electrode opposite the end dielectric, the sliding ground connection isolated from direct contact with the RF hot electrode by the end dielectric;
a seal foil positioned at each sliding ground connection opposite the end dielectric, the seal foil forming an electrical connection between the front face of the elongate housing and the sliding ground connection;
a dielectric spacer within the housing and positioned adjacent the back face of the RF hot electrode;
a grounded plate within the housing and positioned on an opposite side of the dielectric spacer from the RF hot electrode, the grounded plate connected to electrical ground;
a coaxial RF feed line passing through the elongate housing, the coaxial RF feed line including an outer conductor and an inner conductor separated by an insulator, the outer conductor in communication with electrical ground and the inner conductor in electrical communication with the RF hot electrode; and
a plurality of compression elements to provide compressive force to the grounded plate in the direction of the dielectric spacer,
wherein each of the dielectric spacer and the RF hot electrode comprise a plurality of holes therethrough so that a gas in a gas volume can pass through the dielectric spacer and the RF hot electrode into the gap.

14. The plasma source assembly of claim 13, wherein the housing and each of the RF hot electrode, dielectric spacer and grounded plate are wedge-shaped with an inner peripheral edge, an outer peripheral edge and two elongate sides, the first end defining the inner peripheral edge and the second end defining the outer peripheral edge of the housing.

15. A blocker plate for a plasma source assembly, the blocker plate comprising:
an outer peripheral edge;
an electrical center based on a shape of the blocker plate;
at least one first aperture having a first diameter and positioned near the electrical center;
a plurality of third apertures positioned adjacent the outer peripheral edge and defining a field within, the plurality of third apertures having a third diameter different from the first diameter; and
a plurality of second apertures within the field between the plurality of third apertures and the at least one first aperture, each of the plurality of second apertures independently having a second diameter within the range of the third diameter and the first diameter,
wherein the second diameter of any second aperture is less than or equal to about a diameter of an aperture adjacent to the second aperture and closer to the at least one first aperture, and greater than or equal to about a diameter of an aperture adjacent to the second aperture and closer to the third apertures.

16. The blocker plate of claim 15, wherein the plurality of third apertures is spaced from the outer peripheral edge by a distance less than about 15 mm.

17. The blocker plate of claim 15, wherein there are substantially three sets of apertures, a first set of apertures within a region around the electrical center, a second set of apertures around the first set of apertures and the plurality of third apertures around the second set of apertures and adjacent the outer peripheral edge of the blocker plate.

18. The blocker plate of claim 17, wherein the first diameter is in the range of about 2 mm to about 10 mm and the second diameter is in the range of about 1 mm to about 4 mm and the third diameter is in the range of about 0.5 mm to about 3 mm and the first diameter is greater than the second diameter and the second diameter is greater than the third diameter.

19. The blocker plate of claim 17, wherein the first diameter is about 4 mm and the second diameter is about 2 mm and the third diameter is about 1.3 mm.

20. A method comprising:
positioning a substrate in a processing chamber adjacent a blocker plate of a plasma source assembly, the blocker plate having an outer peripheral edge defining a field and a plurality of apertures within the field and extending through the blocker plate, the plurality of apertures comprising a first set of apertures having a first diameter and a second set of apertures having a second diameter different from the first diameter, wherein the first set of apertures are located on an inner portion of the field and the second set of apertures are between the first set of apertures and the outer peripheral edge of the blocker plate; and
generating a plasma within the plasma source assembly so that plasma flows through the blocker plate toward the substrate.
